(19) United States
(12) Patent Application Publication
(10) Pub. No.: US 2025/0063904 A1
(43) Pub. Date: Feb. 20, 2025

(54) DISPLAY DEVICE

(71) Applicant: Samsung Display Co., LTD., Yongin-si (KR)

(72) Inventor: Jin Ho JU, Yongin-si (KR)

(21) Appl. No.: 18/653,875

(22) Filed: May 2, 2024

(30) Foreign Application Priority Data
Aug. 18, 2023 (KR) 10-2023-0108273

(51) Int. Cl. H10K 59/131; H10K 59/121

(52) U.S. Cl. CPC H10K 59/131; H10K 59/1213

(57) ABSTRACT

A display device includes: unit pixel areas; a first thin film transistor in a unit pixel area from among the unit pixel areas, and including a first active layer on a substrate; a second thin film transistor in the unit pixel area, and including a second active layer at a layer different from that of the first active layer; conductive layers in the unit pixel area, and including a plurality of wires and conductive patterns electrically connected to the first thin film transistor and the second thin film transistor; a valley portion surrounding the unit pixel area, and penetrating at least some of insulating layers overlapping with the first thin film transistor and the second thin film transistor; and stacked structures in the valley portion, and including one or more patterns at the same layer as those of the conductive layers, and the insulating layers, and are stacked.

### CROSS-REFERENCE TO RELATED APPLICATION

The present application claims priority to and the benefit of Korean Patent Application No. 10-2023-0108273, filed on Aug. 18, 2023, in the Korean Intellectual Property Office, the entire disclosure of which is incorporated by reference herein.

### BACKGROUND

### 1. Field

Aspects of embodiments of the present disclosure relate to a display device.

### 2. Description of the Related Art

With the advancement of information-oriented society, more and more demand is being placed on display devices for displaying images in various ways. For example, display devices are employed in various electronic devices, such as smartphones, digital cameras, laptop computers, navigation devices, and smart televisions. The display device may be a flat panel display device, such as a liquid crystal display device, a field emission display device, and an organic light emitting display device. From among the flat panel display devices, in a light emitting display device, because each of the pixels of a display panel includes a light emitting element capable of emitting light by itself, an image may be displayed without a backlight unit for providing light to the display panel.

The display device may include pixels that emit predetermined light, and may further include scan lines, data lines, and power lines for driving the pixels, a scan driver that outputs scan signals to the scan lines, and a display driver that outputs data voltages to the data lines.

The above information disclosed in this Background section is for enhancement of understanding of the background of the present disclosure, and therefore, it may contain information that does not constitute prior art.

### SUMMARY

One or more embodiments of the present disclosure may be directed to a display device capable of preventing or substantially preventing damage to circuit elements from impacts applied from the outside.

However, the aspects and features of the present disclosure are not restricted to those described above. The above and other aspects and features of the present disclosure will become more apparent to those having ordinary skill in the art from the below description.

According to one or more embodiments of the present disclosure, a display device includes: a first semiconductor layer including a first active layer on a substrate; a first insulating layer on the first active layer; a first conductive layer on the first insulating layer, and including a first gate electrode and a first capacitor electrode overlapping with the first active layer; a second insulating layer on the first conductive layer; a second conductive layer on the second insulating layer, and including a second capacitor electrode overlapping with the first capacitor electrode; a third insulating layer on the second conductive layer; a second semiconductor layer including a second active layer on the third insulating layer; a fourth insulating layer on the second active layer; a third conductive layer on the fourth insulating layer, and including a second gate electrode overlapping with the second active layer; a fifth insulating layer on the third conductive layer; a valley portion penetrating at least some of the first insulating layer, the second insulating layer, the third insulating layer, the fourth insulating layer, or the fifth insulating layer; a stacked structure including one or more of a plurality of insulating patterns in the valley portion at the same layer as those of the first insulating layer, the second insulating layer, the third insulating layer, the fourth insulating layer, and the fifth insulating layer, respectively; a sixth insulating layer on the fifth insulating layer, and including at least a portion in the valley portion; and a light emitting element on the sixth insulating layer.

In an embodiment, the display device my further include: a barrier layer between the first active layer and the substrate; a lower metal layer between the barrier layer and the first active layer; and a buffer layer between the lower metal layer and the first active layer. The valley portion may penetrate the buffer layer, and the stacked structure may be located directly on the barrier layer.

In an embodiment, a height of the stacked structure measured from the barrier layer may be greater than a height of the second active layer measured from the barrier layer.

In an embodiment, the stacked structure may include one or more of a plurality of metal patterns that are located at the same layer as those of the lower metal layer, the first conductive layer, the second conductive layer, and the third conductive layer, respectively.

In an embodiment, the stacked structure may include one or more of a plurality of semiconductor patterns that are located at the same layer as those of the first semiconductor layer and the second semiconductor layer, respectively.

In an embodiment, a height of the stacked structure may be greater than a depth of the valley portion.

In an embodiment, a height of the stacked structure may be smaller than a depth of the valley portion.

In an embodiment, the stacked structure may include: a first metal pattern at the same layer as that of the lower metal layer; a first insulating pattern at the same layer as that of the buffer layer; a first semiconductor pattern at the same layer as that of the first semiconductor layer; a second insulating pattern at the same layer as that of the first insulating layer; a second metal pattern at the same layer as that of the first conductive layer; a third insulating pattern at the same layer as that of the second insulating layer; a third metal pattern at the same layer as that of the second conductive layer; a fourth insulating pattern at the same layer as that of the third insulating layer; a second semiconductor pattern at the same layer as that of the second semiconductor layer; a fifth insulating pattern at the same layer as that of the fourth insulating layer; a fourth metal pattern at the same layer as that of the third conductive layer; and a sixth insulating pattern at the same layer as that of the fifth insulating layer.

In an embodiment, the first metal pattern, the first insulating pattern, the first semiconductor pattern, the second insulating pattern, the second metal pattern, the third insulating pattern, the third metal pattern, the fourth insulating pattern, the second semiconductor pattern, the fifth insulating pattern, the fourth metal pattern, and the sixth insulating pattern may be sequentially stacked in the stacked structure.

In an embodiment, the sixth insulating layer may surround the stacked structure.

In an embodiment, in the valley portion, a depth of a portion that does not overlap with the first to third conductive layers, the first semiconductor layer, and the second semiconductor layer may be greater than a depth of a portion that overlaps with any one of the first to third conductive layers, the first semiconductor layer, or the second semiconductor layer.

In an embodiment, the first active layer may include silicon, and the second active layer may include an oxide semiconductor.

In an embodiment, the second conductive layer may further include a back gate electrode overlapping with the second active layer.

In an embodiment, the display device my further include a fourth conductive layer between the fifth insulating layer and the sixth insulating layer, the fourth conductive layer including: a first connection electrode connected to the first active layer; and a bridge electrode connected to the second active layer.

According to one or more embodiments of the present disclosure, a display device includes: a plurality of unit pixel areas; a first thin film transistor in a unit pixel area from among the plurality of unit pixel areas, and including a first active layer on a substrate; a second thin film transistor in the unit pixel area, and including a second active layer at a layer different from that of the first active layer; a plurality of conductive layers in the unit pixel area, and including a plurality of wires and conductive patterns electrically connected to the first thin film transistor and the second thin film transistor; a valley portion surrounding the unit pixel area, and penetrating at least some of a plurality of insulating layers overlapping with the first thin film transistor and the second thin film transistor; and a plurality of stacked structures in the valley portion, and including one or more patterns at the same layer as those of the plurality of conductive layers, and the plurality of insulating layers, and are stacked.

In an embodiment, the plurality of unit pixel areas may be located along a first direction and a second direction crossing the first direction, and the valley portion may include a portion extending in the first direction and the second direction.

In an embodiment, a stacked structure from among the plurality of stacked structures may be located in an area where the portion of the valley portion extending in the first direction and the portion of the valley portion extending in the second direction cross each other.

In an embodiment, a stacked structure from among the plurality of stacked structures may include one or more of: a first semiconductor pattern at the same layer as that of the first active layer; and a second semiconductor pattern at the same layer as that of the second active layer.

In an embodiment, a stacked structure from among the plurality of stacked structures may include one or more of: a plurality of metal patterns at the same layer as those of the plurality of conductive layers, respectively; and a plurality of insulating patterns at the same layer as those of the plurality of insulating layers, respectively.

In an embodiment, a stacked structure from among the plurality of stacked structures may not overlap with the conductive patterns and the wires electrically connected to any one of the first thin film transistor and the second thin film transistor.

According to one or more embodiments of the present disclosure, a display device may include a valley portion surrounding an area in which pixel circuits are disposed, and a stacked structure disposed in the valley portion and in which patterns disposed at (e.g., in or on) the same layer as those of a plurality of conductive layers or insulating layers are stacked. The display device may absorb an impact applied from the outside by the valley portion and the stacked structure, and may prevent or substantially prevent the circuit elements of the display device from being damaged.

According to one or more embodiments of the present disclosure, when the display device has flexible characteristics, the valley portion may prevent or substantially prevent cracks that may be formed in a plurality of insulating layers disposed on the substrate when the substrate is folded.

However, the aspects and features of the present disclosure are not limited to those described above, and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is a perspective view of a display device according to an embodiment;

FIG. 2 is a plan view illustrating the display device of FIG. 1;

FIG. 3 is a cross-sectional view taken along the line A-A′ of FIG. 2;

FIG. 4 is a plan view illustrating a display panel according to an embodiment;

FIG. 5 is a pixel circuit diagram of a sub-pixel according to an embodiment;

FIG. 6 is a pixel circuit diagram of a sub-pixel according to an embodiment;

FIG. 7 is a plan view illustrating a disposition of a plurality of pixel circuits disposed in a display area of a display device according to an embodiment;

FIG. 8 is a plan view illustrating pixel circuits disposed in one unit pixel area of FIG. 7;

FIG. 9 is a cross-sectional view taken along the line IX-IX′ of FIG. 8;

FIG. 10 is a cross-sectional view illustrating a second thin film transistor, a valley portion, and a stacked structure of a display device according to an embodiment;

FIG. 11 is a cross-sectional view showing a pixel circuit of a display device according to another embodiment;

FIG. 12 is a cross-sectional view illustrating the second thin film transistor, the valley portion, and the stacked structure of the display device of FIG. 11;

FIG. 13 is a cross-sectional view showing a pixel circuit of a display device according to another embodiment;

FIG. 14 is a cross-sectional view illustrating the second thin film transistor, the valley portion, and the stacked structure of the display device of FIG. 13;

FIG. 15 is a plan view illustrating the disposition of a pixel circuit and a stacked structure disposed in a display area of a display device according to an embodiment; and

FIG. 16 is a plan view illustrating the disposition of a plurality of pixel circuits and a plurality of stacked structures disposed in a display area of a display device according to an embodiment.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense.

For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

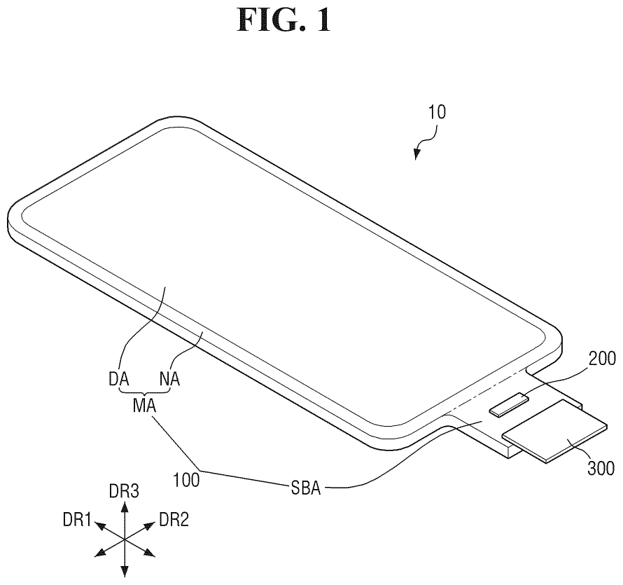

FIG. 1 is a perspective view of a display device according to an embodiment.

Referring to FIG. 1, a display device 10 is a device for displaying a moving image or a still image. The display device 10 may be used as a display screen of various suitable devices, such as a television, a laptop computer, a monitor, a billboard, and an Internet-of-Things (IOT) device, as well as various suitable portable electronic devices, such as a mobile phone, a smartphone, a tablet personal computer (PC), a smart watch, a watch phone, a mobile communication terminal, an electronic notebook, an electronic book, a portable multimedia player (PMP), a navigation device, and an ultra-mobile PC (UMPC).

The display device 10 may be a light emitting display device, such as an organic light emitting display including an organic light emitting diode, a quantum dot light emitting display including a quantum dot light emitting layer, an inorganic light emitting display including an inorganic semiconductor, or a micro light emitting display using a micro or nano light emitting diode (LED). For convenience, the display device 10 may be described in more detail hereinafter in an embodiment of an organic light emitting display device, but the present disclosure is not limited thereto, and the kind of display device 10 is not limited thereto.

In an embodiment, the display device 10 may be formed to be flat or substantially flat. For example, the display device 10 may be formed flat or substantially flat on a plane defined by a first direction DR1 and a second direction DR2, and may have a suitable thickness or height (e.g., a predetermined thickness or height) in a third direction DR3. In another embodiment, the display device 10 may include a curved surface in at least a part including an edge region and/or the like. In addition, the display device 10 may be formed to be flexible so that it can be curved, bent, folded, or rolled.

In some embodiments, with respect to the image display surface of the display device 10, the first direction DR1 may be a vertical direction, a column direction, or a perpendicular direction, and the second direction DR2 may be a direction crossing or intersecting the first direction DR1, for example, such as a widthwise direction, a row direction, or a horizontal direction. The third direction DR3 may be a thickness direction or a height direction of the display device 10.

The display device 10 may include a display panel 100, a driver 200, and a circuit board 300.

The display panel 100 may include a main region MA including a display area DA in which an image is displayed, and a sub-region SBA located on one side of the main region MA.

The main region MA may include the display area DA, and a non-display area NA surrounding (e.g., around a periphery of) the display area DA. The display area DA may be positioned in the center of the main region MA, and may occupy most of the area in the main region MA. The non-display area NA may be positioned at an edge of the main region MA, and may be in contact with the sub-region SBA.

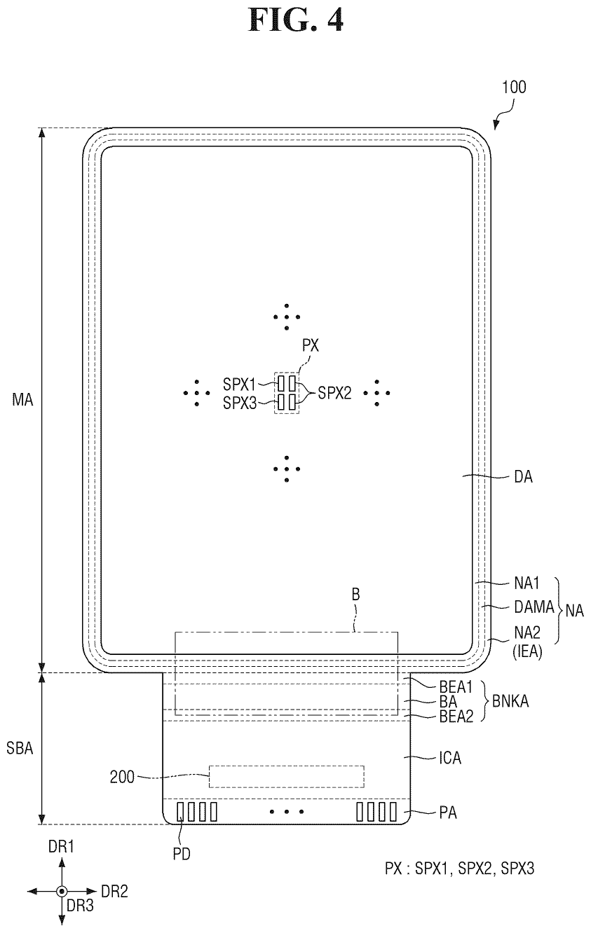

The display area DA may be an area where pixels (e.g., the pixels PX in FIG. 4) are arranged, and an image is displayed by the pixels. In an embodiment, the display area DA may be further provided with sensing patterns (e.g., touch electrodes) for detecting a touch input and the like, and the display area DA may include a sensing area for detecting a touch input by the sensing patterns.

In an embodiment, the display area DA may include a long side extending in the first direction DR1 and a short side extending in the second direction DR2, and may be formed as a plane having an approximately rectangular shape. A corner portion at which the long side and the short side of the display area DA meet each other may be rounded or right-angled. However, the present disclosures is not limited thereto, and the shape of the display area DA may be variously modified as needed or desired. For example, the display area DA may be formed in a polygonal shape other than a quadrilateral shape, a circular shape, an elliptical shape, or the like.

The non-display area NA may be positioned right around (e.g., adjacent to) the display area DA. The non-display area NA may surround (e.g., around a periphery of) the display area DA. An embedded circuit may be disposed in the non-display area NA. For example, an embedded circuit including a scan driving circuit or the like may be disposed in the non-display area NA positioned on one side (e.g., the left side or the right side) or both sides (e.g., opposite sides) of the display area DA.

The sub-region SBA may be located on one side of the main region MA. For example, the sub-region SBA may be a region protruding in the first direction DR1 from one side of the main region MA. For example, the sub-region SBA may protrude in the first direction DR1 from the lower end of the main region MA. In an embodiment, the sub-region SBA may have a narrower width than that of the main region MA. For example, with respect to the second direction DR2, the sub-region SBA may have a narrower width than that of the main region MA.

Wires and pads may be disposed in the sub-region SBA. For example, in the sub-region SBA, the wires and pads connected to the pixels and/or the embedded circuit positioned in the main region MA and to the driver 200 and/or the circuit board 300 positioned in the sub-region SBA may be disposed. As used herein, the term “connect” may include an electrical connection and/or a physical connection.

In an embodiment, the driver 200 (e.g., the display driving circuit) may be mounted in the sub-region SBA. The circuit board 300 may be disposed on a part of the sub-region SBA.

The driver 200 may include a data driving circuit to drive the pixels. In an embodiment, the driver 200 may be formed as an integrated circuit chip (IC), and may be disposed in the sub-region SBA. In another embodiment, the driver 200 may be disposed on the circuit board 300 on the sub-region SBA, or may be disposed on another circuit board connected to the display panel 100 through the circuit board 300.

The circuit board 300 may be disposed on a part of the sub-region SBA. For example, the circuit board 300 may be bonded on the pads positioned on a portion (e.g., a lower edge) of the sub-region SBA, and may supply and/or transmit power voltages and driving signals for driving the display panel 100 to the display panel 100. For example, the circuit board 300 may supply input image data (e.g., digital image data), driving signals including timing signals, and driving voltages to the display panel 100. The circuit board 300 may be a flexible film, such as a flexible printed circuit board (FPCB), a printed circuit board (PCB), or a chip on film (COF), but the present disclosure is not limited thereto.

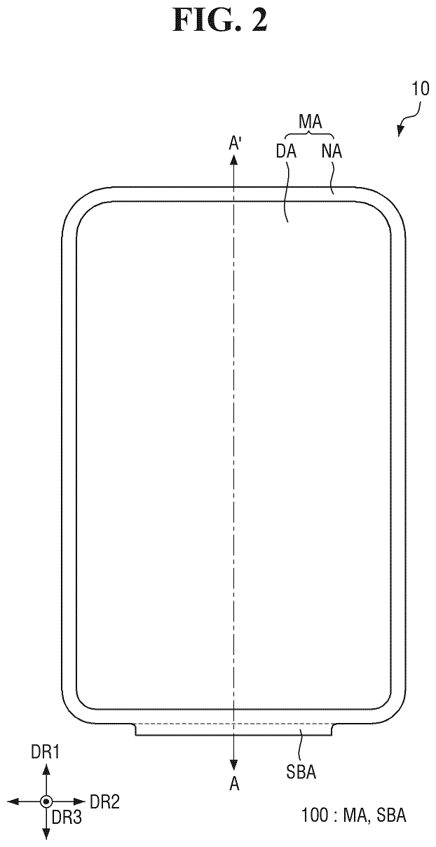

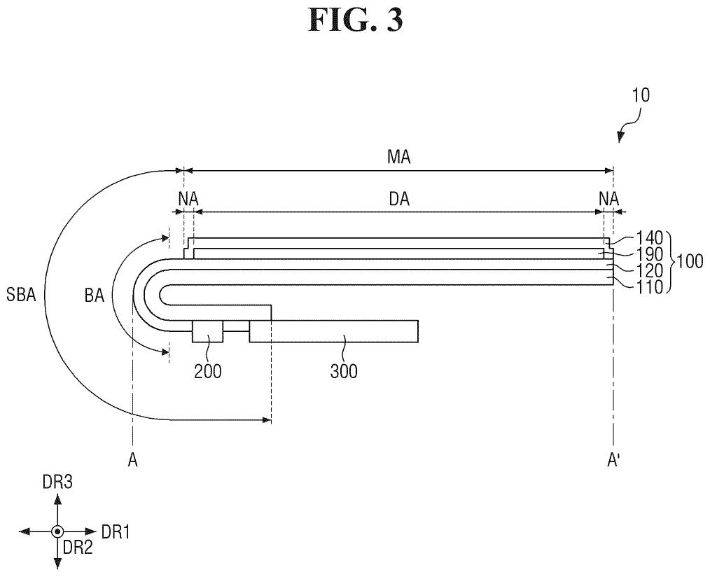

FIG. 2 is a plan view illustrating the display device of FIG. 1. FIG. 3 is a cross-sectional view taken along the line A-A′ of FIG. 2.

FIG. 1 illustrates the display device 10 that is unfolded without being bent, and FIGS. 2 and 3 illustrate the display device 10 that is bent in the sub-region SBA. FIG. 1 shows the sub-region SBA that is unfolded alongside the main region MA, and FIGS. 2 and 3 show a part of the sub-region SBA in a bent state.

Referring to FIGS. 2 and 3, the display panel 100 may include a substrate 110 including the main region MA and the sub-region SBA. The display panel 100 may further include a circuit layer 120, a light emitting element layer 190, and an encapsulation layer 140 sequentially disposed on the substrate 110. The circuit layer 120 may also be positioned in the main region MA and the sub-region SBA on the substrate 110. The light emitting element layer 190 and the encapsulation layer 140 may be positioned on a part of the substrate 110 and the circuit layer 120. For example, the light emitting element layer 190 and the encapsulation layer 140 may be positioned in the main region MA.

In an embodiment, the display device 10 may further include an additional element disposed on the display panel 100. For example, the display device 10 may further include at least one of a sensor layer (e.g., a touch sensor layer), a polarization layer, a color filter layer, and/or a protective layer (e.g., a window) disposed on the encapsulation layer 140. Each of the sensor layer, the polarization layer, the color filter layer, and/or the protective layer may be manufactured integrally with the display panel 100, or may be manufactured separately from the display panel 100 and attached to the display panel 100 through an adhesive layer or the like.

The substrate 110 may include an insulating material, such as a polymer resin. For example, the substrate 110 may be made of polyimide or another insulating material. The substrate 110 may be a flexible substrate that can be transformed, such as being capable of bending, folding, or rolling. As another example, the substrate 110 may include an insulating material such as glass.

The circuit layer 120 may include pixel circuits and wires. For example, the circuit layer 120 may include circuit elements (e.g., pixel transistors and capacitors) constituting the pixel circuits for the pixels, and wires connected to the pixels. In an embodiment, the circuit layer 120 may further include circuit elements constituting an embedded circuit, such as a scan driving circuit, and wires connected to the embedded circuit.

The light emitting element layer 190 may include light emitting elements disposed in emission areas of the pixels. For example, each of the pixels may include at least one light emitting element, and a pixel circuit connected to the light emitting element. Each of the pixels may be located in a pixel region, including the emission area where the light emitting element is disposed, and a pixel circuit area where the pixel circuit is disposed. The emission area and the pixel circuit area of a corresponding pixel may overlap with each other, but the present disclosure is not limited thereto.

For convenience, hereinafter, the circuit layer 120 and the light emitting element layer 190 are separately described, but the present disclosure is not limited thereto. For example, the circuit layer 120 and the light emitting element layer 190 may be integrated together.

The encapsulation layer 140 may cover the light emitting element layer 190, and may extend to the non-display area NA to be in contact with the circuit layer 120. In an embodiment, the encapsulation layer 140 may have a multilayered structure including at least two inorganic encapsulation films overlapping with each other, and at least one organic encapsulation film interposed between the inorganic encapsulation films.

In an embodiment, the display panel 100 may be bent in a bending area BA. The bending area BA may be a part of the sub-region SBA, and may be spaced apart from the main region MA.

The substrate 110 and the circuit layer 120 may be bent in the bending area BA corresponding to a partial section of the sub-region SBA. Accordingly, a bezel area that may be recognized by a user as the non-display area NA may be reduced or minimized.

FIG. 4 is a plan view illustrating a display panel according to an embodiment. FIG. 4 shows the display panel 100 in an unbent and unfolded state.

Referring to FIG. 4, the display panel 100 may include the main region MA and the sub-region SBA. The main region MA may include the display area DA and the non-display area NA. The sub-region SBA may include a bank area BNKA, a driving circuit mounting area ICA, and a pad area PA.

The display area DA may be an area where a plurality of pixels PX are disposed. The pixels PX and wires (or some of the wires) connected to the pixels PX may be disposed in the display area DA.

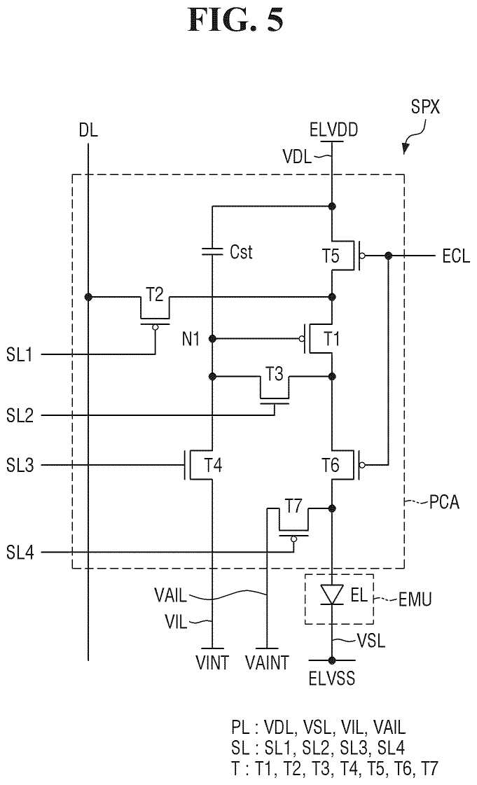

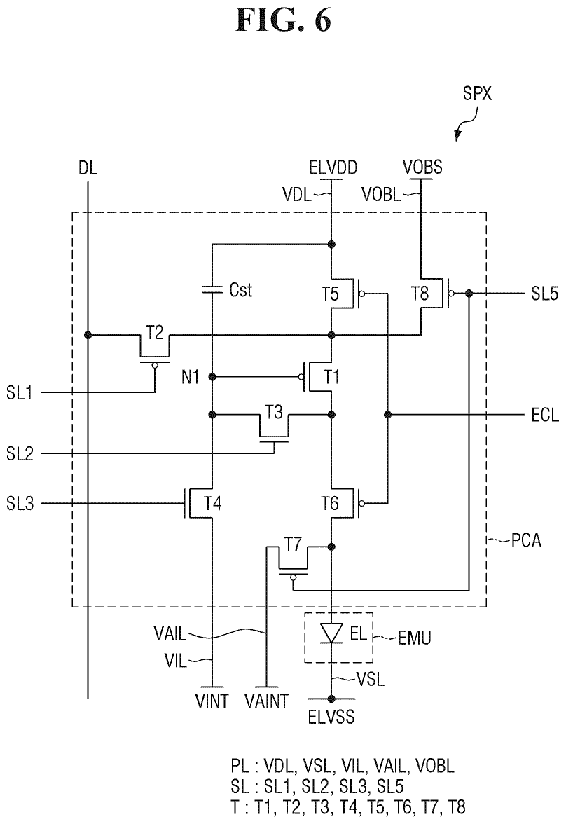

The pixels PX may be provided in the circuit layer 120 and the light emitting element layer 190 of the display panel 100. As an example, each pixel PX may include a pixel circuit (e.g., the pixel circuit PCA of FIG. 5 or FIG. 6) including circuit elements disposed at (e.g., in or on) the circuit layer 120, and a light emitting element (e.g., the light emitting element EL of FIG. 5 or FIG. 6) disposed at (e.g., in or on) the light emitting element layer 190.

The pixels PX may include at least two color sub-pixels SPX that emit light of different colors from each other. For example, the pixels PX may include first color sub-pixels SPX1 for emitting light of a first color (e.g., red light), second color sub-pixels SPX2 for emitting light of a second color (e.g., green light), and third color sub-pixels SPX3 for emitting light of a third color (e.g., blue light).

At least one first color sub-pixel SPX1, at least one second color sub-pixel SPX2, and at least one third color sub-pixel SPX3 that are adjacent to each other may constitute one unit pixel PX. For example, one first color sub-pixel SPX1, two second color sub-pixels SPX2, and one third color sub-pixel SPX3 that are adjacent to each other may constitute one unit pixel PX. Each unit pixel PX may emit light of various suitable colors, including white light, by color mixing of the light emitted from the sub-pixels SPX1, SPX2, and SPX3 constituting the unit pixel PX. In an embodiment, the first color sub-pixels SPX1 and the third color sub-pixels SPX3 may be arranged alternately with each other in the first direction DR1 and/or the second direction DR2, and the second color sub-pixels SPX2 may be arranged continuously and/or sequentially in the first direction DR1. The kind, the shape, and/or the arrangement structure of the sub-pixels SPX1, SPX2, and SPX3 may be variously modified as needed or desired. In addition, the kind, the number, the ratio, and/or the arrangement structure of the sub-pixels SPX1, SPX2, and SPX3 constituting each unit pixel PX may also be variously modified as needed or desired.

The encapsulation layer 140 may be disposed on the pixels PX. For example, the encapsulation layer 140 may be provided in at least the display area DA to cover the pixels PX, and a part of the encapsulation layer 140 may extend into the non-display area NA.

Wires may be provided in the circuit layer 120, and may be positioned in the display area DA and the non-display area NA. In addition, wires may be positioned also in the sub-region SBA. For example, the wires may extend from the sub-region SBA through the non-display area NA to the display area DA.

The non-display area NA may be located around (e.g., adjacent to) the display area DA. For example, the non-display area NA may be an edge area of the main region MA positioned outside the display area DA.

The non-display area NA may include a dam area DAMA spaced apart from the display area DA, a first non-display area NA1 between the display area DA and the dam area DAMA, and a second non-display area NA2 outside the dam area DAMA. The dam area DAMA may be an area in which a dam surrounding (e.g., around a periphery of) the display area DA is disposed. The second non-display area NA2 may include an inorganic encapsulation area IEA (also referred to as a “bonding area”), in which the inorganic encapsulation layers of the encapsulation layer 140 are bonded to each other.

The sub-region SBA may include the bank area BNKA, the driving circuit mounting area ICA, and the pad area PA sequentially disposed on one side of the main region MA. Wires (or parts of wires), banks, and the pads PD may be disposed in the sub-region SBA. At least some of the wires may extend into the main region MA and be connected to the pixels PX.

The bank area BNKA may be an area in which a bank including at least one organic layer is disposed. In an embodiment, the bank area BNKA may include the bending area BA. For example, the bank area BNKA may include the bending area BA that is spaced apart from the main region MA, and a first edge area BEA1 and a second edge area BEA2 positioned on both sides (e.g., opposite sides) of the bending area BA in the first direction DR1. The bank may be provided in the bending area BA and in peripheral areas thereof (e.g., in the first edge area BEA1 and the second edge area BEA2 of the bank area BNKA) to cover the wires passing through the bending area BA. The display panel 100 may be bent in the bending area BA, such that a part of the sub-region SBA may be positioned behind (e.g., underneath) the main region MA.

The driving circuit mounting area ICA may be an area in which the driver 200 is disposed. Pads for connecting at least some of the wires to the driver 200 may be disposed in the driving circuit mounting area ICA. For example, in the driving circuit mounting area ICA, input pads for connecting the driver 200 to specific pads (e.g., data input pads) of the pad area PA, and output pads for connecting the driver 200 to the pixels PX, may be disposed.

In some embodiments, the driver 200 may not be disposed on the display panel 100. In this case, the display panel 100 may not include the driving circuit mounting area ICA, and wires (e.g., only wires) may be disposed in an area between the bank area BNKA and the pad area PA.

The pad area PA may be an area where the pads PD for connecting the display panel 100 and/or the driver 200 to the circuit board 300 and the like are disposed. The circuit board 300 may be disposed or bonded onto the pad area PA.

A plurality of pads PD including power pads and signal pads connected to the pixels PX, the driver 200, and/or the embedded circuit may be disposed in the pad area PA. Power voltages for driving the pixels PX, the driver 200, and/or the embedded circuit or the like may be supplied to the power pads. Driving signals and/or image data for driving the pixels PX, the driver 200, and/or the embedded circuit or the like may be supplied to the signal pads. The kind, the location, the arrangement order, and/or the number of the pads PD may be variously modified as needed or desired.

FIG. 5 is a pixel circuit diagram of a sub-pixel according to an embodiment. FIG. 6 is a pixel circuit diagram of a sub-pixel according to an embodiment.

FIGS. 5 and 6 illustrate different embodiments related to the pixel circuit PCA and the wires connected to the pixel circuit PCA. The configuration of the pixel circuit PCA and the kind and the number of the wires connected to the pixel circuit PCA may be variously modified as needed or desired.

FIG. 5 illustrates an embodiment in which a pixel circuit (e.g., each pixel circuit) PCA includes first to seventh transistors T1 to T7. In an embodiment, scan lines SL connected to the sub-pixel SPX of FIG. 5 may include a first scan line SL1, a second scan line SL2, a third scan line SL3, and a fourth scan line SL4. Power lines PL connected to the sub-pixel SPX of FIG. 5 may include a first pixel power line VDL, a second pixel power line VSL, a first initialization power line VIL, and a second initialization power line VAIL. The sub-pixel SPX of FIG. 5 may be further connected to an emission control line ECL.

FIG. 6 illustrates an embodiment in which a pixel circuit (e.g., each pixel circuit) PCA includes first to eighth transistors T1 to T8. In an embodiment, the scan lines SL connected to the sub-pixel SPX of FIG. 6 may include the first scan line SL1, the second scan line SL2, the third scan line SL3, and a fifth scan line SL5. The power lines PL connected to the sub-pixel SPX of FIG. 6 may include the first pixel power line VDL, the second pixel power line VSL, the first initialization power line VIL, the second initialization power line VAIL, and a bias power line VOBL. The sub-pixel SPX of FIG. 6 may be further connected to an emission control line ECL.

Referring to FIG. 5, the sub-pixel SPX may include a light emitting unit (e.g., a light emitting device) EMU including at least one light emitting element EL, and the pixel circuit PCA (also referred to as a “pixel driver”) connected to the light emitting unit EMU.

The light emitting element EL may be connected between the pixel circuit PCA and the second pixel power line VSL to which the second pixel power voltage ELVSS is applied. In an embodiment, the second pixel power voltage ELVSS may be a low potential pixel driving voltage. The light emitting element EL, which is a light source of the pixel PX, may emit light in response to a driving current supplied from the pixel circuit PCA.

The light emitting element EL may be an organic light emitting diode, but the present disclosure is not limited thereto. For example, the light emitting element EL may be an inorganic light emitting element, a quantum dot light emitting element, or another kind of light emitting element.

The pixel circuit PCA may control a light emitting timing and a luminance of the light emitting element EL by controlling the driving current supplied to the light emitting element EL. The pixel circuit PCA may include at least one pixel transistor T and a capacitor Cst. In an embodiment, the pixel circuit PCA may include a plurality of pixel transistors T including the first to seventh transistors T1 to T7.

The first transistor T1 may include a gate electrode connected to a first node N1, a first electrode electrically connected to the first pixel power line VDL through the fifth transistor T5, and a second electrode electrically connected to the light emitting unit EMU through the sixth transistor T6. One of the first electrode or the second electrode may be a source electrode, and the other one may be a drain electrode. The first transistor T1 may control a source-drain current (hereinafter referred to as a “driving current”) flowing between the first electrode and the second electrode according to a voltage (e.g., the voltage of the first node N1 corresponding to the voltage of the data signal) applied to the gate electrode. For example, the first transistor T1 may be a driving transistor of the sub-pixel SPX.

The second transistor T2 may include a gate electrode connected to the first scan line SL1, a first electrode connected to the data line DL, and a second electrode connected to the first electrode of the first transistor T1. The second transistor T2 may be turned on by the first scan signal supplied to the first scan line SL1 to electrically connect the first electrode of the first transistor T1 to the data line DL. When the second transistor T2 is turned on, the voltage of the data signal supplied to the data line DL may be applied to the first electrode of the first transistor T1.

The third transistor T3 may include a gate electrode connected to the second scan line SL2, a first electrode connected to the second electrode of the first transistor T1, and a second electrode connected to a gate electrode (or the first node N1) of the first transistor T1. The third transistor T3 may be turned on by the second scan signal supplied to the second scan line SL2 to electrically connect the gate electrode of the first transistor T1 to the second electrode. When the third transistor T3 is turned on, the first transistor T1 may be driven as a diode, or in other words, the first transistor T1 may be diode-connected by the third transistor T3.

The fourth transistor T4 may include a gate electrode connected to the third scan line SL3, a first electrode connected to the gate electrode of the first transistor T1, and a second electrode connected to the first initialization power line VIL. The fourth transistor T4 may be turned on by the third scan signal supplied to the third scan line SL3 to electrically connect the gate electrode of the first transistor T1 to the first initialization power line VIL. When the fourth transistor T4 is turned on, a first initialization voltage VINT (e.g., the gate initialization voltage) of the first initialization power line VIL may be applied to the gate electrode of the first transistor T1.

The fifth transistor T5 may include a gate electrode connected to the emission control line ECL, a first electrode connected to the first pixel power line VDL, and a second electrode connected to the first electrode of the first transistor T1. The fifth transistor T5 may be turned on by the emission control signal supplied to the emission control line ECL, and thus, may electrically connect the first electrode of the first transistor T1 to the first pixel power line VDL to which a first pixel power voltage ELVDD is applied. When the fifth transistor T5 is turned on, the first pixel power voltage ELVDD may be applied to the first electrode of the first transistor T1. In an embodiment, the first pixel power voltage ELVDD may be a high potential pixel driving voltage.

The sixth transistor T6 may include a gate electrode connected to the emission control line ECL, a first electrode connected to the second electrode of the first transistor T1, and a second electrode connected to the light emitting element EL. The sixth transistor T6 may be turned on by the emission control signal supplied to the emission control line ECL to electrically connect the first transistor T1 to the light emitting element EL. When all of the fifth transistor T5 and the sixth transistor T6 are turned on, the driving current having a magnitude corresponding to the voltage of the gate electrode of the first transistor T1 may flow through the light emitting element EL.

The seventh transistor T7 may include a gate electrode connected to the fourth scan line SL4, a first electrode connected to the anode electrode of the light emitting element EL, and a second electrode connected to the second initialization power line VAIL. The seventh transistor T7 may be turned on by the fourth scan signal supplied to the fourth scan line SL4 to electrically connect the anode electrode of the light emitting element EL to the second initialization power line VAIL. The fourth scan signal may be the same signal as or a different signal from the first scan signal. When the seventh transistor T7 is turned on, the second initialization voltage VAINT (e.g., an anode initialization voltage) of the second initialization power line VAIL may be applied to the anode electrode of the light emitting element EL.

The capacitor Cst may be connected between the gate electrode of the first transistor T1 and the first pixel power line VDL. The capacitor Cst may be charged with a voltage corresponding to the voltage of the data signal applied to the gate electrode of the first transistor T1.

An active layer (e.g., a semiconductor pattern including a channel region) of each of the pixel transistors T (e.g., the first to seventh transistors T1 to T7) may include one semiconductor material from among polysilicon, amorphous silicon, or an oxide semiconductor. In an embodiment, some of the pixel transistors T and some others thereof may be formed of transistors of different conductivity types from each other. In addition, some of the pixel transistors T and some others thereof may include different types of semiconductor materials from each other.

For example, the first, second, fifth, sixth, and seventh transistors T1, T2, T5, T6, and T7 may be formed of P-type transistors (e.g., P-type MOSFETs) including the active layers formed of polysilicon, and the third and fourth transistors T3 and T4 may be formed of N-type transistors (e.g., N-type MOSFETs) including the active layers formed of an oxide semiconductor. In an embodiment, the transistors including the active layers formed of polysilicon and the transistors including the active layers formed of an oxide semiconductor may be disposed at (e.g., in or on) different layers in the circuit layer 120.

Referring to FIG. 6 in addition to FIG. 5, the pixel circuit PCA may further include the eighth transistor T8. The eighth transistor T8 may include a gate electrode connected to the fifth scan line SL5, a first electrode connected to the bias power line VOBL, and a second electrode connected to the first electrode of the first transistor T1. The eighth transistor T8 may be turned on by the fifth scan signal supplied to the fifth scan line SL5 to electrically connect the first electrode of the first transistor T1 to the bias power line VOBL. When the eighth transistor T8 is turned on, the bias voltage VOBS supplied to the bias power line VOBL may be applied to the first electrode of the first transistor T1. In an embodiment, the bias voltage VOBS may have a voltage level suitable for compensating for a hysteresis characteristic of the first transistor T1. As the eighth transistor T8 is turned on, the first electrode of the first transistor T1 may be initialized to the bias voltage VOBS.

In the embodiment illustrated in FIG. 6, the gate electrode of the seventh transistor T7 may be connected to the fifth scan line SL5. Accordingly, the seventh transistor T7 may be turned on by the fifth scan signal supplied to the fifth scan line SL5 to connect the anode electrode of the light emitting element EL to the second initialization power line VAIL.

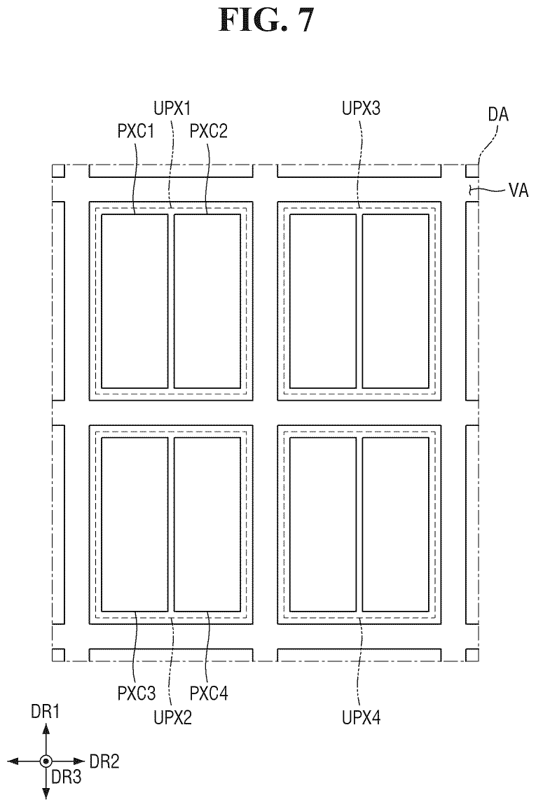

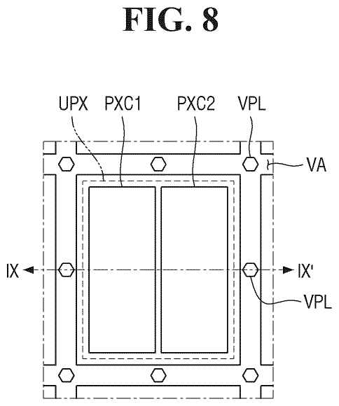

FIG. 7 is a plan view illustrating a disposition of a plurality of pixel circuits disposed in a display area of a display device according to an embodiment. FIG. 8 is a plan view illustrating pixel circuits disposed in one unit pixel area of FIG. 7.

Referring to FIGS. 7 and 8, the display device 10 may include a plurality of pixel circuits PXC (e.g., PXC1, PXC2, PXC3, and PXC4) disposed in the display area DA. Each of the plurality of pixel circuits PXC may be electrically connected to the light emitting element EL included in the sub-pixels SPX1, SPX2, and SPX3. A plurality of circuit elements included in the pixel circuit PXC may be applied with electrical signals for the light emitting element EL to emit light.

The plurality of pixel circuits PXC may be arranged in the first direction DR1 and the second direction DR2. For example, two pixel circuits PXC that are adjacent to each other in the second direction DR2 may constitute one unit pixel area UPX (e.g., UPX1, UPX2, UPX3, and UPX4), and may be arranged in the first direction DR1 and the second direction DR2. The first pixel circuit PXC1 and the second pixel circuit PXC2 that are adjacent to each other in the second direction DR2 may constitute one first unit pixel area UPX1. The third pixel circuit PXC3 and the fourth pixel circuit PXC4 that are adjacent to each other in the second direction DR2 may constitute one second unit pixel area UPX2. The first unit pixel area UPX1 and the second unit pixel area UPX2 may be arranged in the first direction DR1. Each of the third unit pixel area UPX3 and the fourth unit pixel area UPX4 may include two pixel circuits that are adjacent to each other in the second direction DR2, and may be arranged in the first direction DR1. The first unit pixel area UPX1 and the second unit pixel area UPX2 may be arranged in the second direction DR2 with respect to the third unit pixel area UPX3 and the fourth unit pixel area UPX4, respectively.

The plurality of wires, conductive patterns, and semiconductor layers constituting the pixel circuit may repeat the same patterns with respect to the one unit pixel area UPX rather than the pixel circuit. For example, the disposition structure of the wires, conductive patterns, and semiconductor layers of the first unit pixel area UPX1 may have the same or substantially the same disposition structure in the second unit pixel area UPX2, the third unit pixel area UPX3, and the fourth unit pixel area UPX4. Each of the first pixel circuit PXC1 and the second pixel circuit PXC2 may have a symmetric or substantially symmetric structure in the disposition of the conductive patterns and the semiconductor layers, and the conductive patterns and patterns of semiconductor layers constituting the two pixel circuits PXC1 and PXC2 may be repeatedly arranged on the entire surface of the display area DA.

According to an embodiment, the display device 10 may include a valley portion VA disposed to surround (e.g., around a periphery of) the unit pixel area UPX. The valley portion VA may surround (e.g., around a periphery of) the one unit pixel area UPX, and may surround (e.g., around peripheries of) a plurality of unit pixel areas UPX on the entire surface of the display area DA. The valley portion VA may be disposed to extend in the first direction DR1 and the second direction DR2, and the two pixel circuits PXC may be disposed in an area that the valley portions VA surround by crossing or intersecting each other. The plurality of unit pixel areas UPX may be disposed to be spaced apart from each other with the valley portion VA disposed therebetween, and may be isolated within an area surrounded by the valley portion VA.

The valley portion VA may be formed to penetrate a plurality of conductive layers constituting the pixel circuit PXC and an interlayer insulating layer disposed between the semiconductor layers. The valley portion VA may prevent an external impact applied to the display device 10 from being transmitted to the elements of the pixel circuit PXC. In addition, the display device 10 may include the valley portion VA surrounding the area in which the pixel circuits PXC are disposed, so that when the display device 10 including the flexible substrate 110 is folded, cracks that may be formed on a plurality of insulating layers may be prevented or substantially prevented.

According to an embodiment, the display device 10 may further include a plurality of stacked structures VPL disposed in the valley portion VA. The stacked structure VPL may be a structure in which a plurality of conductive layers and a semiconductor layer constituting the pixel circuit PXC, and at least one of insulating layers disposed therebetween are stacked. The stacked structure VPL may be disposed in the valley portion VA to protect the circuit elements from an external impact. The impact applied to the display device 10 may be absorbed by the valley portion VA and/or the stacked structure VPL surrounding the pixel circuit PXC.

FIG. 8 illustrates that the stacked structures VPL are disposed in a portion of the valley portion VA extending in the first direction DR1, a portion of the valley portion VA extending in the second direction DR2, and an area in which the portions cross or intersect each other, respectively, so that eight stacked structures VPL are disposed per one unit pixel area UPX. However, the present disclosure is not limited thereto. The stacked structures VPL may be disposed in a larger or smaller number per one unit pixel area UPX. Because the stacked structure VPL has a structure in which the conductive layers and/or the semiconductor layer constituting the pixel circuit PXC are stacked, the position and/or the number of the stacked structures VPL may be variously modified depending on the disposition structure of the pixel circuit PXC. Hereinafter, the structures of the display device 10, the valley portion VA, and the stacked structure VPL will be described in more detail with reference to the other drawings.

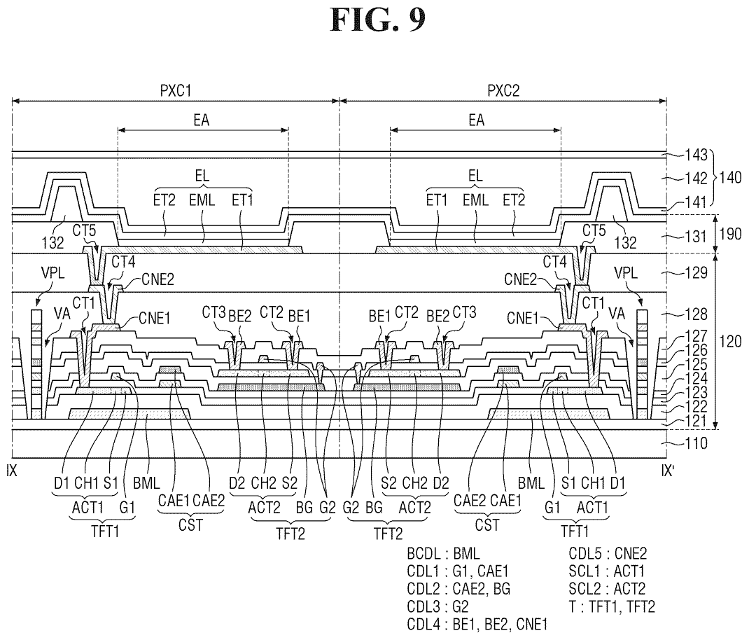

FIG. 9 is a cross-sectional view taken along the line IX-IX′ of FIG. 8. FIG. 9 schematically illustrates a cross section of a part of the display area DA corresponding to an area in which the one unit pixel area UPX is disposed and positioned. FIG. 9 illustrates the cross section crossing a part of the first pixel circuit PXC1 and the second pixel circuit PXC2 that are adjacent to each other in the second direction DR2.

Referring to FIG. 9, the display panel 100 may include the substrate 110, the circuit layer 120 disposed on the substrate 110, the light emitting element layer 190, and the encapsulation layer 140. The circuit layer 120, the light emitting element layer 190, and the encapsulation layer 140 may be sequentially arranged or stacked on the substrate 110 along the third direction DR3.

The substrate 110 may include (e.g., may be made of) a suitable material having a flexible characteristic capable of bending, folding, rolling, or the like. The substrate 110 may be formed of an insulating material, such as a polymer resin. For example, the substrate 110 may be made of polyimide.

The circuit layer 120 may include the pixel circuit PXC and the wires. For example, the circuit layer 120 may include the circuit elements (e.g., the pixel transistors T and the capacitor Cst) constituting the pixel circuit PXC for each sub-pixel SPX, and the wires (e.g., the various power lines and signal lines including the power lines PL, the scan lines SL, the emission control lines ECL, and the data lines DL) electrically connected to the sub-pixels SPX.

From among the elements that may be provided at (e.g., in or on) the circuit layer 120, FIG. 9 illustrates a first thin film transistor TFT1 (also referred to as a “first pixel transistor”) included in the pixel circuit PXC of a corresponding sub-pixel SPX, a second thin film transistor TFT2 (also referred to as a “second pixel transistor”), and a capacitor Cst. The first thin film transistor TFT1 may be a first type transistors (e.g., a P-type transistor) including a first semiconductor material (e.g., polysilicon) from among the pixel transistors T constituting the pixel circuit PXC. For example, the first thin film transistor TFT1 may be one of the first, second, fifth, sixth, seventh, and/or eighth transistors T1, T2, T5, T6, T7, and/or T8. FIG. 9 illustrates, as an example of the first thin film transistor TFT1, one transistor (e.g., the sixth transistor T6 of FIG. 5 or FIG. 6) that is connected to the light emitting element EL through at least one connection electrode (e.g., a first connection electrode CNE1 and a second connection electrode CNE2) from among the first type transistors. The second thin film transistor TFT2 may be a second type transistor (e.g., an N-type transistor) including a second semiconductor material (e.g., an oxide semiconductor) from among the pixel transistors T. For example, the second thin film transistor TFT2 may be one of the third or fourth transistors T3 or T4.

The cross sections of the sub-pixels SPX may be variously modified according to each of the sub-pixels SPX and the type and/or structure of the display panel 100 including the sub-pixel SPX. For example, the positions and the order of formation of the first thin film transistor TFT1, the second thin film transistor TFT2, and the capacitor Cst may be variously modified as needed or desired.

The circuit layer 120 may include semiconductor layers for forming the circuit elements, the wires, or the like, conductive layers, and insulating layers disposed between and/or around the conductive layers and the semiconductor layers. For example, the circuit layer 120 may include a first semiconductor layer SCL1 (e.g., a polysilicon semiconductor layer), a first insulating layer 123 (e.g., a first gate insulating layer), a first conductive layer CDL1 (e.g., a first gate conductive layer), a second insulating layer 124 (e.g., a second gate insulating layer), a second conductive layer CDL2 (e.g., a second gate conductive layer), a third insulating layer 125 (e.g., a first interlayer insulating layer), a second semiconductor layer SCL2 (e.g., an oxide semiconductor layer), a fourth insulating layer 126 (e.g., a third gate insulating layer), a third conductive layer CDL3 (e.g., a third gate conductive layer), a fifth insulating layer 127 (e.g., a second interlayer insulating layer), a fourth conductive layer CDL4 (e.g., a first source-drain conductive layer), and a sixth insulating layer 128 (e.g., a first via layer or a first planarization layer), which may be sequentially disposed on the substrate 110 with respect to the third direction DR3. In an embodiment, the circuit layer 120 may further include a fifth conductive layer CDL5 (e.g., a second source-drain conductive layer) and a seventh insulating layer 129 (e.g., a second via layer or a second planarization layer) sequentially disposed on the sixth insulating layer 128. In an embodiment, the circuit layer 120 may further include a lower conductive layer BCDL disposed between the substrate 110 and the first semiconductor layer SCL1, a barrier layer 121 disposed between the substrate 110 and the lower conductive layer BCDL, and a buffer layer 122 disposed between the lower conductive layer BCDL and the first semiconductor layer SCL1.

The barrier layer 121 may be disposed on the substrate 110. The barrier layer 121 may protect the elements disposed at (e.g., in or on) the circuit layer 120 and the light emitting element layer 190 from moisture permeating through the substrate 110 that may be susceptible to moisture permeation. The barrier layer 121 may include at least one inorganic layer containing an inorganic insulating material (e.g., silicon nitride, silicon oxide, silicon oxynitride, titanium oxide, aluminum oxide, or another suitable inorganic insulating material). The material of the barrier layer 121 may be variously modified as needed or desired.

The lower conductive layer BCDL may be disposed on the barrier layer 121. The lower conductive layer BCDL may include a lower metal layer BML overlapping with the active layer (e.g., the first active layer ACT1 and/or the second active layer ACT2) of the at least one pixel transistor T, and/or at least one wire (or a part of the at least one wire). FIG. 9 illustrates that the lower metal layer BML is disposed to overlap with (e.g., only with) the first active layer ACT1 of the first thin film transistor TFT1 and the capacitor electrodes CAE1 and CAE2 of the capacitor Cst, but the present disclosure is not limited thereto. For example, the lower metal layer BML may be patterned into an appropriate size and/or shape as needed or desired, and may be disposed on a part of the pixel circuit PXC, or may be disposed on the entire surface of the pixel circuit PXC. For example, the lower metal layer BML may be disposed only in a part of the pixel area to overlap with the first transistor T1 illustrated in FIGS. 5 and 6.

In an embodiment, the lower metal layer BML may also be utilized as a light blocking pattern and/or a back-gate electrode of at least one pixel transistor T, or the like.

The buffer layer 122 may be disposed on the lower conductive layer BCDL to cover the lower conductive layer BCDL. The buffer layer 122 may include at least one inorganic layer containing an inorganic insulating material.

The first thin film transistor TFT1, the second thin film transistor TFT2, and the capacitor Cst may be disposed on one surface of the substrate 110 including the buffer layer 122. The first thin film transistor TFT1 may include the first active layer ACT1 and a first gate electrode G1. The second thin film transistor TFT2 may include the second active layer ACT2 and a second gate electrode G2. In an embodiment, the second thin film transistor TFT2 may include a back-gate electrode BG. The capacitor Cst may include the first capacitor electrode CAE1 and the second capacitor electrode CAE2.

The first semiconductor layer SCL1 may be disposed on the buffer layer 122. The first semiconductor layer SCL1 may include the first active layer ACT1 of the first thin film transistor TFT1. For example, the first semiconductor layer SCL1 may include the first active layer ACT1 of each of the first, second, fifth, sixth, seventh, and/or eighth transistors T1, T2, T5, T6, T7, and/or T8.

The first active layer ACT1 may be provided at (e.g., in or on) the first semiconductor layer SCL1, and may include a first semiconductor material (e.g., polysilicon). The first active layer ACT1 may include a first channel region CH1, a first source region S1, and a first drain region D1. The first channel region CH1 may overlap with the first gate electrode G1 in the third direction DR3. The first source region S1 may be disposed on one side of the first channel region CH1, and the first drain region D1 may be disposed on another side of the first channel region CH1. The first source region S1 and the first drain region D1 may be regions formed to have a conductivity by doping ions or impurities into the semiconductor for forming the first active layer ACT1. In an embodiment, the first source region S1 may be a source electrode of the first thin film transistor TFT1. In another embodiment, the first thin film transistor TFT1 may include a separate source electrode connected to the first source region S1. In an embodiment, the first drain region D1 may be a drain electrode of the first thin film transistor TFT1. In another embodiment, the first thin film transistor TFT1 may include a separate drain electrode connected to the first drain region D1.

The first insulating layer 123 may be disposed on the first semiconductor layer SCL1. The first insulating layer 123 may cover the first semiconductor layer SCL1.

The first conductive layer CDL1 may be disposed on the first insulating layer 123. The first conductive layer CDL1 may include the first gate electrode G1 of the first thin film transistor TFT1. The first gate electrode G1 may be disposed to overlap with a part of the first active layer ACT1 (e.g., with the first channel region CH1). In an embodiment, the first conductive layer CDL1 may further include at least one wire (or a part of the at least one wire), a metal pattern (e.g., a bridge pattern), and/or a capacitor electrode. For example, the first conductive layer CDL1 may further include the first capacitor electrode CAE1 of the capacitor Cst.

In an embodiment, the first capacitor electrode CAE1 may be integrally formed with (e.g., together with) the gate electrode of at least one first thin film transistor TFT1. For example, the first capacitor electrode CAE1 may be integrally formed with the gate electrode of the first transistor T1 illustrated in FIGS. 5 and 6. For example, the first capacitor electrode CAE1 and the gate electrode of the first transistor T1 may be formed as one conductive pattern, and the second capacitor electrode CAE2 may be disposed to overlap with the conductive pattern.

The second insulating layer 124 may be disposed on the first conductive layer CDL1. The second insulating layer 124 may cover the first conductive layer CDL1.

The second conductive layer CDL2 may be disposed on the second insulating layer 124. The second conductive layer CDL2 may include one electrode of the capacitor Cst, for example, such as the second capacitor electrode CAE2. In an embodiment, the second conductive layer CDL2 may further include at least one electrode, a wire (or a part of the at least one wire), and/or a metal pattern (e.g., a bridge pattern). For example, the second conductive layer CDL2 may further include the back-gate electrode BG connected to the second gate electrode G2 of the second thin film transistor TFT2.

The third insulating layer 125 may be disposed on the second conductive layer CDL2. The third insulating layer 125 may cover the second conductive layer CDL2.

The second semiconductor layer SCL2 may be disposed on the third insulating layer 125. The second semiconductor layer SCL2 may include the second active layer ACT2 of the second thin film transistor TFT2. For example, the second semiconductor layer SCL2 may include the second active layer ACT2 of each of the third and fourth transistors T3 and T4.

The second active layer ACT2 may be provided at (e.g., in or on) the second semiconductor layer SCL2, and may include a second semiconductor material (e.g., an oxide semiconductor) different from the first semiconductor material. For example, the second active layer ACT2 may be include IGZO (indium (In), gallium (Ga), zinc (Zn), and oxygen (O)), IGZTO (indium (In), gallium (Ga), zinc (Zn), tin (Sn), and oxygen (O)), or IGTO (indium (In), gallium (Ga), tin (Sn), and oxygen (O)).

The second active layer ACT2 may include a second channel region CH2, a second source region S2, and a second drain region D2. The second channel region CH2 may overlap with the second gate electrode G2 in the third direction DR3. The second source region S2 may be disposed on one side of the second channel region CH2, and the second drain region D2 may be disposed on another side of the second channel region CH2. The second source region S2 and the second drain region D2 may be conductive regions by doping ions or impurities into the semiconductor for forming the second active layer ACT2. In an embodiment, the second source region S2 may be a source electrode of the second thin film transistor TFT2. In another embodiment, the second thin film transistor TFT2 may include a separate source electrode connected to the second source region S2. In an embodiment, the second drain region D2 may be a drain electrode of the second thin film transistor TFT2. In another embodiment, the second thin film transistor TFT2 may include a separate drain electrode connected to the second drain region D2.

The fourth insulating layer 126 may be disposed on the second semiconductor layer SCL2. The fourth insulating layer 126 may cover the second semiconductor layer SCL2.

The third conductive layer CDL3 may be disposed on the fourth insulating layer 126. The third conductive layer CDL3 may include the second gate electrode G2 of the second thin film transistor TFT2. The second gate electrode G2 may be disposed to overlap with a part of the second active layer ACT2 (e.g., with the second channel region CH2). In an embodiment, the third conductive layer CDL3 may further include at least one wire (or a part of the at least one wire), a metal pattern (e.g., a bridge pattern), and/or a capacitor electrode.

In an embodiment, each of the electrodes, the conductive patterns, and/or the wires provided at (e.g., in or on) the lower conductive layer BCDL, the first conductive layer CDL1, the second conductive layer CDL2, and the third conductive layer CLD3 may include a conductive material (e.g., molybdenum (Mo), aluminum (Al), chromium (Cr), gold (Au), titanium (Ti), nickel (Ni), neodymium (Nd), copper (Cu), at least one of other metals, any suitable alloys thereof, or other suitable conductive materials), and may each may have a single layer or multilayered structure. For example, each of the electrodes, the conductive patterns, and/or the wires provided in the lower conductive layer BCDL, the first conductive layer CDL1, the second conductive layer CDL2, and the third conductive layer CLD3 may include molybdenum (Mo) or other suitable metal materials. At least two conductive layers from among the lower conductive layer BCDL, the first conductive layer CDL1, the second conductive layer CDL2, and/or the third conductive layer CLD3 may include the same material as each other or may include different materials from each other. The materials of each of the lower conductive layer BCDL, the first conductive layer CDL1, the second conductive layer CDL2, and the third conductive layer CLD3 are not particularly limited, and may be variously modified as needed or desired.

The fifth insulating layer 127 may be disposed on the third conductive layer CDL3. The fifth insulating layer 127 may cover the third conductive layer CDL3.

In an embodiment, the first insulating layer 123, the second insulating layer 124, the third insulating layer 125, the fourth insulating layer 126, and the fifth insulating layer 127 may be an inorganic insulating layer including an inorganic insulating material (e.g., silicon nitride, silicon oxide, silicon oxynitride, titanium oxide, aluminum oxide, or another suitable inorganic insulating material), and may each may have a single layer or multilayered structure. At least two insulating layers from among the first insulating layer 123, the second insulating layer 124, the third insulating layer 125, the fourth insulating layer 126, and/or the fifth insulating layer 127 may include the same material as each other or may include different materials from each other. The materials of each of the first insulating layer 123, the second insulating layer 124, the third insulating layer 125, the fourth insulating layer 126, and the fifth insulating layer 127 may be variously modified as needed or desired.

The fourth conductive layer CDL4 may be disposed on the fifth insulating layer 127. The fourth conductive layer CDL4 may include the first connection electrode CNE1 (or a drain electrode of the first thin film transistor TFT1), a first bridge electrode BE1 (or a source electrode of the second thin film transistor TFT2), and a second bridge electrode BE2 (or a drain electrode of the second thin film transistor TFT2). The first connection electrode CNE1 may be provided at (e.g., in or on) the fourth conductive layer CDL4, and may be connected to the first drain region D1 of the first active layer ACT1 through a first contact hole CT1 penetrating the first insulating layer 123, the second insulating layer 124, the third insulating layer 125, the fourth insulating layer 126, and the fifth insulating layer 127. The first bridge electrode BE1 may be provided at (e.g., in or on) the fourth conductive layer CDL4, and may be connected to the second source region S2 of the second active layer ACT2 through a second contact hole CT2 penetrating the fourth insulating layer 126 and the fifth insulating layer 127. The second bridge electrode BE2 may be connected to the second drain region D2 of the second active layer ACT2 through a third contact hole CT3 penetrating the fourth insulating layer 126 and the fifth insulating layer 127. In an embodiment, the fourth conductive layer CDL4 may further include at least one wire (or a part of the at least one wire), and/or a metal pattern (e.g., a bridge pattern). For example, the fourth conductive layer CDL4 may include a part of the power line PL (e.g., the first pixel power line VDL and/or the second pixel power line VSL) provided inside and/or outside the display area DA.

The valley portion VA may be formed to penetrate at least some of the plurality of insulating layers disposed on the barrier layer 121. For example, the valley portion VA may penetrate at least some of the buffer layer 122, the first insulating layer 123, the second insulating layer 124, the third insulating layer 125, the fourth insulating layer 126, and/or the fifth insulating layer 127. The valley portion VA may penetrate at least some of the plurality of insulating layers overlapping with the first thin film transistor TFT1 and the second thin film transistor TFT2. The valley portion VA may have a maximum depth when formed to penetrate all of the buffer layer 122 and the first to fifth insulating layers 123, 124, 125, 126, and 127. The valley portion VA may be formed not to penetrate the semiconductor layers SCL1 and SCL2 and the conductive layers CDL1, CDL2, and CDL3 disposed between the buffer layer 122 and the fifth insulating layer 127. From among the valley portions VA, the valley portion VA formed on a portion overlapping with the semiconductor layers SCL1 and SCL2 and the conductive layers CDL1, CDL2, CDL3, and CDL4 may have a smaller depth. FIG. 9 illustrates a portion of the valley portion VA penetrating all of the buffer layer 122 and the first to fifth insulating layers 123, 124, 125, 126, and 127. However, the valley portion VA may overlap with at least one of the semiconductor layers SCL1 and/or SCL2 and/or at least one of the conductive layers CDL1, CDL2, and/or CDL3 depending on its position, and in this case, the depth thereof may be relatively smaller.

The stacked structure VPL may be disposed within the valley portion VA. The stacked structure VPL may have a structure in which one or more patterns disposed at (e.g., in or on) the same layer as those of the lower conductive layer BCDL to the fifth insulating layer 127 are stacked on one another.

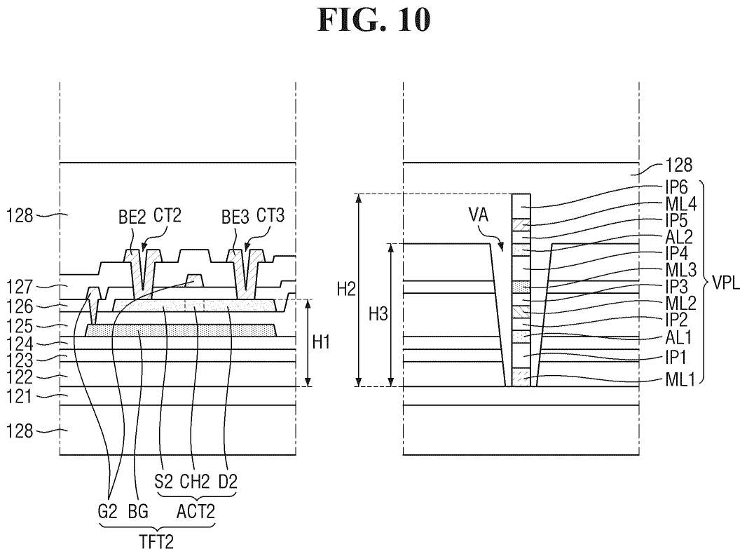

FIG. 10 is a cross-sectional view illustrating a second thin film transistor, a valley portion, and a stacked structure of a display device according to an embodiment.

Referring to FIG. 10 in addition to FIG. 9, in the display device 10 according to an embodiment, the stacked structure VPL may include a plurality of patterns disposed at (e.g., in or on) the same layer as those of the lower conductive layer BCDL, the first semiconductor layer SCL1, the second semiconductor layer SCL2, the first to third conductive layers CDL1, CDL2, and CDL3, the buffer layer 122, and the first to fifth insulating layers 123, 124, 125, 126, and 127, respectively. For example, the stacked structure VPL may include a first metal pattern ML1 disposed at (e.g., in or on) the same layer as that of the lower conductive layer BCDL, a second metal pattern ML2 disposed at (e.g., in or on) the same layer as that of the first conductive layer CDL1, a third metal pattern ML3 disposed at (e.g., in or on) the same layer as that of the second conductive layer CDL2, and a fourth metal pattern ML4 disposed at (e.g., in or on) the same layer as that of the third conductive layer CDL3. In addition, the stacked structure VPL may include a first semiconductor pattern AL1 disposed at (e.g., in or on) the same layer as that of the first semiconductor layer SCL1, and a second semiconductor pattern AL2 disposed at (e.g., in or on) the same layer as that of the second semiconductor layer SCL2. In addition, the stacked structure VPL may further include a first insulating pattern IP1 disposed at (e.g., in or on) the same layer as that of the buffer layer 122, and second to sixth insulating patterns IP2, IP3, IP4, IP5, and IP6 disposed at (e.g., in or on) the same layer as those of the first insulating layer 123 to the fifth insulating layer 127, respectively.

The stacking order of each layer of the stacked structure VPL may be the same as the stacking order from the lower conductive layer BCDL to the fifth insulating layer 127. For example, the stacked structure VPL may have a structure in which the first metal pattern ML1, the first insulating pattern IP1, the first semiconductor pattern AL1, the second insulating pattern IP2, the second metal pattern ML2, the third insulating pattern IP3, the third metal pattern ML3, the fourth insulating pattern IP4, the second semiconductor pattern AL2, the fifth insulating pattern IP5, the fourth metal pattern ML4, and the sixth insulating pattern IP6 are sequentially stacked. FIG. 10 illustrates a case where the stacked structure VPL includes all of the patterns disposed at (e.g., in or on) the same layer as the layers from the lower conductive layer BCDL to the fifth insulating layer 127, but the present disclosure is not limited thereto. The stacked structure VPL may be formed with only some of the layers being stacked.

A plurality of patterns included in the stacked structure VPL may be portions remaining after being patterned in a formation process of the same layer as those of the plurality of patterns. For example, when the semiconductor layer, the conductive layers, and the wires constituting the circuit element are formed in the formation process of the lower conductive layer BCDL, the first and second semiconductor layers SCL1 and SCL2, and the first to third conductive layers CDL1, CDL2, and CDL3, the plurality of patterns of the stacked structure VPL may be formed together therewith. In addition, in the process of forming the valley portion VA, the portions of the buffer layer 122 and the first to fifth insulating layers 123, 124, 125, 126, and 127 overlapping with the patterns may be stacked together without being removed to form the stacked structure VPL.

According to an embodiment, the display device 10 may have a height H2 of the stacked structure VPL that is greater than a height H1 at which the second active layer ACT2 of the second thin film transistor TFT2 including an oxide semiconductor is disposed. The stacked structure VPL, along with the valley portion VA, may prevent or substantially prevent an external impact from being transmitted to the circuit elements of the pixel circuit PXC. As such, the stacked structure VPL may be formed to be higher than at least a position at which the first thin film transistor TFT1 and the second thin film transistor TFT2 of the pixel circuit PXC are disposed, so that the first thin film transistor TFT1 and the second thin film transistor TFT2 may be prevented or substantially prevented from being damaged by the impact. Because the second thin film transistor TFT2 is disposed at a higher position than that of the first thin film transistor TFT1, the height H2 of the stacked structure VPL may be greater than at least the height H1 of the position at which the second active layer ACT2 of the second thin film transistor TFT2 is disposed. Each of the height H2 of the stacked structure VPL and the height H1 of the position at which the second active layer ACT2 is disposed may be the height measured from the top surface of the barrier layer 121 or the top surface of the substrate 110 in the third direction DR3.

As described above, a depth H3 of the valley portion VA may vary depending on whether or not the valley portion VA overlaps with a conductive layer or a semiconductor layer. However, the maximum depth H3 of the valley portion VA may be the depth of the portion that does not overlap with the conductive layer or the semiconductor layer, and penetrates all the way from the buffer layer 122 to the fifth insulating layer 127. The maximum depth H3 of the valley portion VA may be greater than the height H1 of the position at which the second active layer ACT2 of the second thin film transistor TFT2 is disposed, such that the valley portion VA may absorb the impact that may be applied to the circuit elements of the pixel circuit PXC.

In addition, the height H2 of the stacked structure VPL may be greater than the maximum depth H3 of the valley portion VA, but the present disclosure is not limited thereto. The height H2 of the stacked structure VPL may vary depending on the number of stacked patterns, and thus, may be unrelated to the maximum depth H3 of the valley portion VA. However, as described above, the height H2 of the stacked structure VPL may be greater than at least the height H1 of the position at which the second active layer ACT2 of the second thin film transistor TFT2 is disposed.

The sixth insulating layer 128 may be disposed on the fourth conductive layer CDL4. The sixth insulating layer 128 may cover the fourth conductive layer CDL4. In addition, the sixth insulating layer 128 may fill the inside of the valley portion VA, and may surround (e.g., around a periphery of) the stacked structure VPL.

The fifth conductive layer CDL5 may be disposed on the sixth insulating layer 128. The fifth conductive layer CDL5 may include the second connection electrode CNE2. The second connection electrode CNE2 may be provided in the fifth conductive layer CDL5, and may be connected to the first connection electrode CNE1 through a fourth contact hole CT4 (e.g., a first via hole) penetrating the sixth insulating layer 128. In an embodiment, the fifth conductive layer CDL5 may further include at least one wire (or a part of the at least one wire), and/or a metal pattern (e.g., a bridge pattern). For example, the fifth conductive layer CDL5 may include a part of the power line PL (e.g., the first pixel power line VDL and/or the second pixel power line VSL) provided inside and/or outside the display area DA.

In an embodiment, each of the electrodes, the conductive patterns, and/or the wires provided at (e.g., in or on) the fourth conductive layer CDL4 and the fifth conductive layer CDL5 may include a conductive material (e.g., molybdenum (Mo), aluminum (Al), chromium (Cr), gold (Au), titanium (Ti), nickel (Ni), neodymium (Nd), copper (Cu), at least one of other suitable metals, suitable alloys thereof, or other suitable conductive materials), and may have a single layer or multilayered structure. For example, each of the electrodes, the conductive patterns, and/or the wires provided at (e.g., in or on) the fourth conductive layer CDL4 and the fifth conductive layer CDL5 may be formed of a triple layered structure of titanium/aluminum/titanium (Ti/Al/Ti). The fourth conductive layer CDL4 and the fifth conductive layer CDL5 may include the same material as each other or may include different materials from each other. The materials of each of the fourth conductive layer CDL4 and the fifth conductive layer CDL5 may be variously modified as needed or desired.

The seventh insulating layer 129 may be disposed on the fifth conductive layer CDL5. The seventh insulating layer 129 may cover the fifth conductive layer CDL5.

In an embodiment, the sixth insulating layer 128 and the seventh insulating layer 129 may be an organic insulating layer including an organic insulating material (e.g., an acrylic resin, an epoxy resin, a phenolic resin, a polyamide resin, a polyimide resin, or another suitable organic insulating material) to planarize or substantially planarize the circuit layer 120, and each may have a single layer or multilayered structure. The sixth insulating layer 128 and the seventh insulating layer 129 may include the same material as each other or may include different materials from each other. The materials of each of the sixth insulating layer 128 and the seventh insulating layer 129 may be variously modified as needed or desired.

The light emitting element layer 190 may include a pixel defining layer 131 that partitions emission areas EA of the pixels PX, and the light emitting elements EL respectively positioned in the emission areas EA. In an embodiment, the light emitting element layer 190 may further include a spacer 132 disposed on a part of the pixel defining layer 131.

Each of the light emitting elements EL may include a first electrode ET1 (e.g., an anode electrode) connected to at least one transistor T (e.g., the first thin film transistor TFT1) included in the corresponding sub-pixel SPX through the first connection electrode CNE1 and/or the second connection electrode CNE2, and the light emitting layer EML and a second electrode ET2 (e.g., a cathode electrode) sequentially disposed on the first electrode ET1. In an embodiment, the light emitting element EL may further include a first intermediate layer (e.g., a hole layer including a hole transport layer) interposed between the first electrode ET1 and the light emitting layer EML, and a second intermediate layer (e.g., an electron layer including an electron transport layer) interposed between the light emitting layer EML and the second electrode ET2.

The first electrode ET1 of the light emitting element EL may include a conductive material, and may be disposed on the circuit layer 120. For example, the first electrode ET1 may be disposed on the seventh insulating layer 129 to correspond to each emission area EA. The first electrode ET1 may be connected to the second connection electrode CNE2 through a fifth contact hole CT5 (e.g., a second via hole) penetrating the seventh insulating layer 129.

In an embodiment, the first electrode ET1 may include a metal material having a high reflectivity. For example, the first electrode ET1 may have a single-layer structure of molybdenum (Mo), titanium (Ti), copper (Cu), or aluminum (AI), or may have a multilayered structure (e.g., ITO/Mg, ITO/MgF, ITO/Ag, and/or ITO/Ag/ITO) including indium-tin-oxide (ITO), indium-zinc-oxide (IZO), zinc oxide (ZnO), or indium oxide (In2O3), and silver (Ag), magnesium (Mg), aluminum (AI), platinum (Pt), lead (Pb), gold (Au), or nickel (Ni).

The light emitting layer EML of the light emitting element EL may include a high molecular material or a low molecular material. In an embodiment, the light emitting layer EML may be disposed for each sub-pixel SPX, and the light emitting layer EML of each sub-pixel SPX may emit a visible light of a color corresponding to the corresponding sub-pixel SPX. In another embodiment, the light emitting layer EML may be a common layer shared by the sub-pixels SPX of different colors, and a wavelength conversion layer and/or color filters corresponding to the color (or wavelength band) of the light desired to be emitted from each sub-pixel SPX may be arranged in the emission areas EA of at least some of the sub-pixels SPX.

The second electrode ET2 of the light emitting element EL includes a conductive material, and may be connected to the second pixel power line VSL. In an embodiment, the second electrode ET2 may be a common layer formed across the entire display area DA to cover the light emitting layer EML and the pixel defining layer 131. In an embodiment, the second electrode ET2 may be formed of a transparent conductive material (TCO), such as ITO or IZO, capable of transmitting light, or a semi-transmissive conductive material, such as magnesium (Mg), silver (Ag), or an alloy of magnesium (Mg) and silver (Ag). When the second electrode ET2 includes (e.g., is made of) a semi-transmissive conductive material, an improvement in light output efficiency due to a micro cavity effect may be provided.

The pixel defining layer 131 may have an opening for (e.g., corresponding to) each of the emission areas EA, and the pixel defining layer 131 may surround (e.g., around peripheries of) the emission areas EA. For example, the pixel defining layer 131 may be formed to cover an edge of the first electrode ET1 of the light emitting element EL, and may include an opening exposing the remaining portion of the first electrode ET1. A region where the exposed first electrode ET1 and the light emitting layer EML overlap with each other (or a region including the same) may be defined as the emission area EA of each pixel PX.

In an embodiment, the pixel defining layer 131 may include at least one organic layer containing an organic insulating material. For example, the pixel defining layer 131 may include an acrylic resin, an epoxy resin, a phenolic resin, a polyamide resin, a polyimide resin, an unsaturated polyester resin, a polyphenylene ether resin, a polyphenylenesulfide resin, benzocyclobutene (BCB), or other suitable organic insulating materials.

The spacer 132 may be disposed on a part of the pixel defining layer 131. The spacer 132 may include at least one organic layer containing an organic insulating material. The spacer 132 may include the same material as that of the pixel defining layer 131, or may include a different material from that of the pixel defining layer 131. In an embodiment, the pixel defining layer 131 and the spacer 132 may be sequentially formed through separate mask processes. In another embodiment, the pixel defining layer 131 and the spacer 132 may be concurrently or simultaneously formed using a halftone mask. In this case, the pixel defining layer 131 and the spacer 132 may be regarded as a single insulating layer that is integral with each other. The organic insulating material constituting the spacer 132 is not particularly limited, and may be variously modified as needed or desired.

The encapsulation layer 140 may be disposed on the light emitting element layer 190 in the main region MA. For example, the encapsulation layer 140 may be disposed in the display area DA and the non-display area NA to cover the light emitting element layer 190. The encapsulation layer 140 may block the permeation of oxygen and/or moisture into the light emitting element layer 190, and may reduce an electrical or physical impact to the circuit layer 120 and the light emitting element layer 190.

In an embodiment, the encapsulation layer 140 may include a first inorganic encapsulation layer 141, an organic encapsulation layer 142, and a second inorganic encapsulation layer 143 that are sequentially disposed on the light emitting element layer 190. The first inorganic encapsulation layer 141 and the second inorganic encapsulation layer 143 may include an inorganic material, and the organic encapsulation layer 142 may include an organic material.

The display device 10 according to an embodiment includes the valley portion VA surrounding (e.g., around a periphery of) an area in which the plurality of pixel circuits PXC are disposed and the stacked structure VPL disposed in the valley portion VA, so that damage to the circuit elements from the impact applied from the outside of the display device 10 may be prevented or substantially prevented. In addition, when the display device 10 has flexible characteristics, the valley portion VA may prevent or substantially prevent cracks that may form in a plurality of insulating layers disposed on the substrate 110 when the substrate 110 is folded.

Hereinafter, various embodiments of the display device 10 will be described with reference to other drawings.

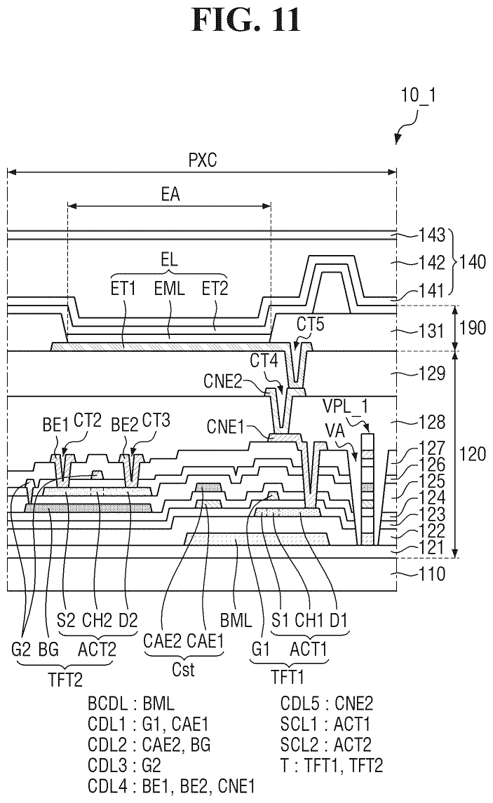

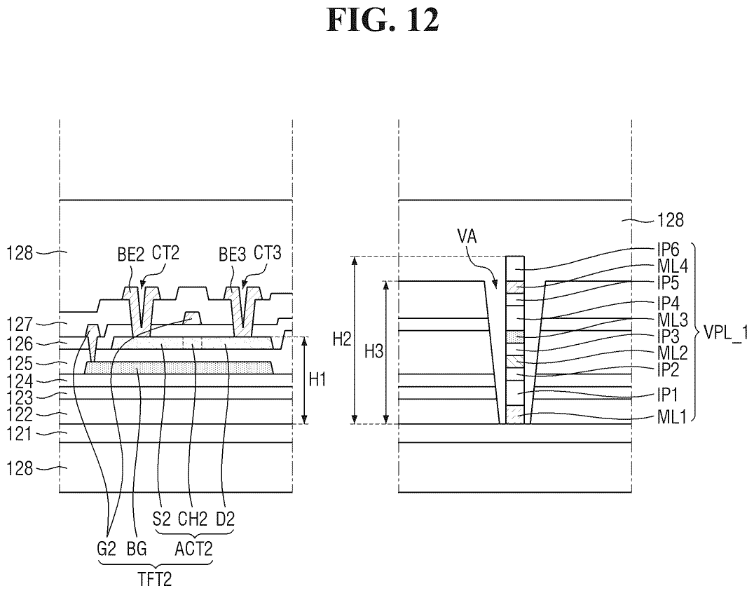

FIG. 11 is a cross-sectional view showing a pixel circuit of a display device according to another embodiment. FIG. 12 is a cross-sectional view illustrating the second thin film transistor, the valley portion, and the stacked structure of the display device of FIG. 11.

Referring to FIGS. 11 and 12, in a display device 10_1, a stacked structure VPL_1 may be disposed in the valley portion VA, and may include a plurality of layers. However, unlike the embodiment illustrated in FIG. 10, the stacked structure VPL_1 may not include some layers. In an embodiment, the stacked structure VPL_1 may include a plurality of metal patterns ML1, ML2, ML3, and ML4 and a plurality of insulating patterns IP1, IP2, IP3, IP4, IP5, and IP6, but may not include the semiconductor patterns AL1 and AL2. In the stacked structure VPL_1, the first metal pattern ML1, the first insulating pattern IP1, the second insulating pattern IP2, the second metal pattern ML2, the third insulating pattern IP3, the third metal pattern ML3, the fourth insulating pattern IP4, the fifth insulating pattern IP5, the fourth metal pattern ML4, and the sixth insulating pattern IP6 may be sequentially stacked. In the stacked structure VPL_1, the first insulating pattern IP1 and the second insulating pattern IP2 that are respectively disposed at (e.g., in or on) the same layer as those of the buffer layer 122 and the first gate insulating layer 123 disposed on the upper layer and lower layer of the first semiconductor layer SCL1 may be in contact with each other. In the stacked structure VPL_1, the fourth insulating pattern IP4 and the fifth insulating pattern IP5 that are respectively disposed at (e.g., in or on) the same layer as those of the third insulating layer 125 and the fourth insulating layer 126 disposed on the upper layer and lower layer of the second semiconductor layer SCL2 may be in contact with each other.

The height of the stacked structure VPL_1 may be variously modified when the height H2 of the stacked structure VPL_1 is greater than at least the height H1 at which the second semiconductor layer ACT2 of the second thin film transistor TFT2 is disposed. In the stacked structure VPL_1, patterns of only some of the layers from the lower conductive layer BCDL to the fifth insulating layer 127 may be stacked. In the display device 10_1 according to the present embodiment, the height H2 of the stacked structure VPL_1 may be greater than the height H1 of the second semiconductor layer ACT2 of the second thin film transistor TFT2. Although the stacked structure VPL_1 does not include the semiconductor patterns AL1 and AL2, the height H2 thereof may be greater than the depth H3 of the valley portion VA.

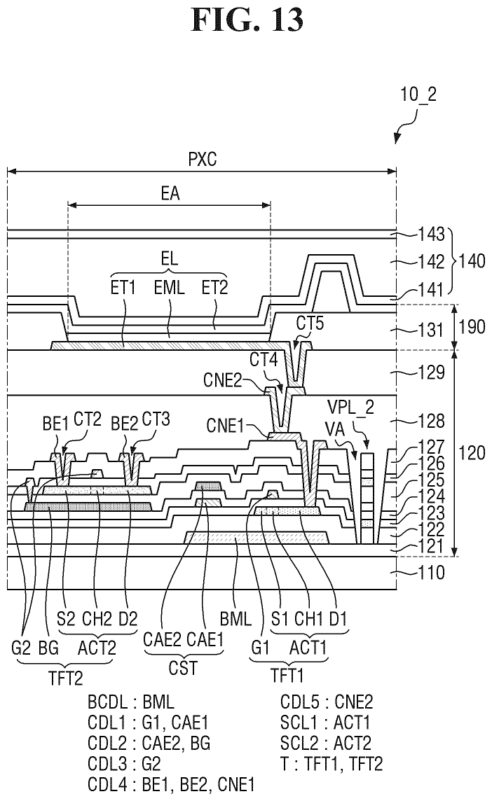

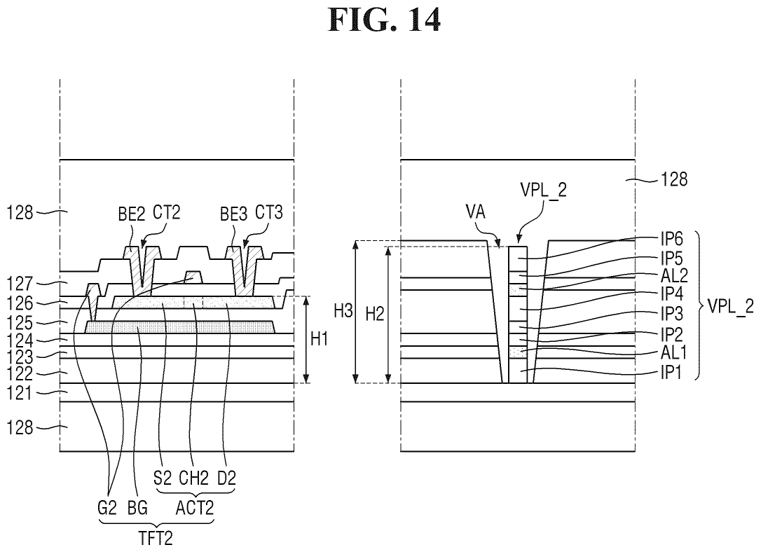

FIG. 13 is a cross-sectional view showing a pixel circuit of a display device according to another embodiment. FIG. 14 is a cross-sectional view illustrating the second thin film transistor, the valley portion, and the stacked structure of the display device of FIG. 13.

Referring to FIGS. 13 and 14, in a display device 10_2, a stacked structure VPL_2 may be disposed in the valley portion VA, and may include a plurality of layers. However, unlike the embodiment illustrated in FIG. 10, the stacked structure VPL_2 may not include some layers. In an embodiment, the stacked structure VPL_2 may include the plurality of insulating patterns IP1, IP2, IP3, IP4, IP5, and IP6 and a plurality of semiconductor patterns AL1 and AL2, but may not include the metal patterns ML1, ML2, ML3, and ML4. In the stacked structure VPL_2, the first insulating pattern IP1, the first semiconductor pattern AL1, the second insulating pattern IP2, the third insulating pattern IP3, the fourth insulating pattern IP4, the second semiconductor pattern AL2, the fifth insulating pattern IP5, and the sixth insulating pattern IP6 may be sequentially stacked. In the stacked structure VPL_2, the second insulating pattern IP2, the third insulating pattern IP3, and the fourth insulating pattern IP4 may be directly in contact with one another, and the fifth insulating pattern IP5 and the sixth insulating pattern IP6 may be directly in contact with each other.

The height of the stacked structure VPL_2 may be variously modified when the height H2 of the stacked structure VPL_2 is greater than at least the height H1 at which the second semiconductor layer ACT2 of the second thin film transistor TFT2 is disposed. In the stacked structure VPL_2, patterns of only some of the layers from the lower conductive layer BCDL to the fifth insulating layer 127 may be stacked. In the display device 10_2 according to the present embodiment, the height H2 of the stacked structure VPL_2 may be greater than the height H1 of the second semiconductor layer ACT2 of the second thin film transistor TFT2. The stacked structure VPL_2 may not include the metal patterns ML1, ML2, ML3, and ML4, and the height H2 thereof may be smaller than the depth H3 of the valley portion VA.

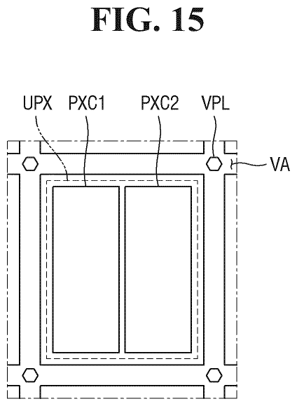

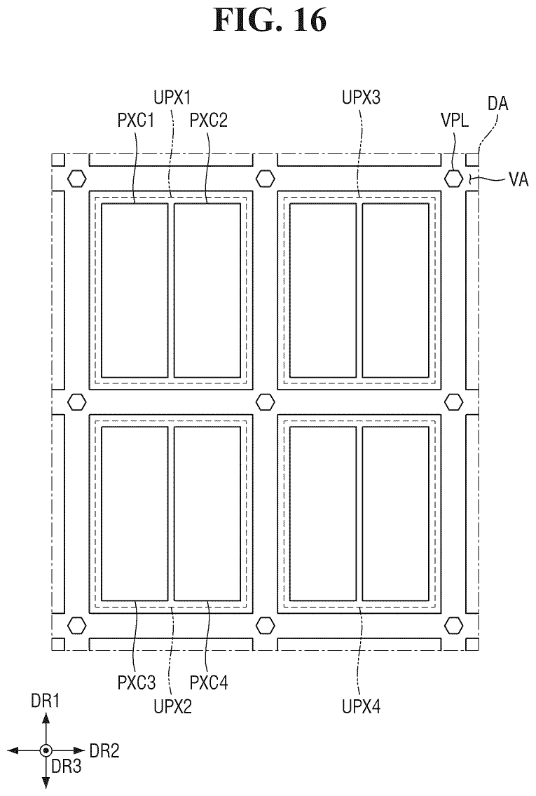

FIG. 15 is a plan view illustrating the disposition of a pixel circuit and a stacked structure disposed in a display area of a display device according to an embodiment. FIG. 16 is a plan view illustrating the disposition of a plurality of pixel circuits and a plurality of stacked structures disposed in a display area of a display device according to an embodiment.

Referring to FIGS. 15 and 16, in the display device 10, the plurality of stacked structures VPL may be disposed, and each of the stacked structures VPL may be disposed in an area in which the valley portions VA cross or intersect with each other in the first direction DR1 and the second direction DR2. Each of the stacked structures VPL may be disposed in an area in which the valley portions VA cross or intersect near (e.g., adjacent to) a vertex of the unit pixel area UPX. The display device 10 may have four stacked structures VPL disposed with respect to the one unit pixel area UPX. As another example, nine stacked structures VPL may be disposed with respect to the four unit pixel areas UPX1, UPX2, UPX3, and UPX4.

The stacked structure VPL may be disposed in the valley portion VA, and may have a structure in which patterns that are respectively disposed at (e.g., in or on) the same layer as those of a plurality of conductive layers CDL1, CDL2, CDL3, and CDL4, the semiconductor layers SCL1 and SCL2, and insulating layers constituting the pixel circuit PXC are stacked. The stacked structure VPL may include a plurality of wires disposed in the plurality of conductive layers CDL1, CDL2, CDL3, and CDL4 of the pixel circuit PXC, and the wires may extend in the first direction DR1 and the second direction DR2 to be disposed across the pixel circuit PXC or the unit pixel area UPX. A portion of the valley portion VA crossing or intersecting in the first direction DR1 and the second direction DR2 may overlap with the wires, and the portion of the valley portion VA overlapping with the wires may have a smaller depth than other portions thereof.

The wires may be a plurality of wires that are disposed at (e.g., in or on) the lower conductive layer BCDL and the first to third conductive layers CDL1, CDL2, and CDL3 and connected to the pixel circuit PXC, or conductive patterns electrically connected to the thin film transistors TFT1 and TFT2. For example, the wires may be the plurality of scan lines SL, data lines DL, emission control lines ECL, power lines PL, or the like described above with reference to FIGS. 5 and 6.

It may be desirable for the stacked structure VPL to have as many patterns as possible that are stacked to absorb an external impact. It may be desirable for the stacked structure VPL to have a plurality of layers that are stacked and disposed not to overlap with the plurality of wires disposed in the pixel circuit PXC and the display area DA. In the display device 10, the stacked structure VPL may be disposed in an area in which the stacked structure VPL does not overlap with the plurality of wires disposed in the pixel circuit PXC. In some embodiments, the wires extend in the first direction DR1 and the second direction DR2, and are disposed to cross the pixel circuit PXC, so that the stacked structure VPL may be disposed in an area in which the stacked structure VPL does not overlap with the pixel circuit PXC in the first direction DR1 or the second direction DR2 at a boundary of the unit pixel areas UPX. However, the present disclosure is not limited thereto, and when the plurality of stacked structures VPL are disposed in areas in which the plurality of stacked structures VPL do not overlap with the wires at the boundaries of the unit pixel areas UPX, the plurality of stacked structures VPL may overlap with the pixel circuit PXC in the first direction DR1 or the second direction DR2.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a first semiconductor layer comprising a first active layer on a substrate;
a first insulating layer on the first active layer;
a first conductive layer on the first insulating layer, and comprising a first gate electrode and a first capacitor electrode overlapping with the first active layer;
a second insulating layer on the first conductive layer;
a second conductive layer on the second insulating layer, and comprising a second capacitor electrode overlapping with the first capacitor electrode;
a third insulating layer on the second conductive layer;
a second semiconductor layer comprising a second active layer on the third insulating layer;
a fourth insulating layer on the second active layer;
a third conductive layer on the fourth insulating layer, and comprising a second gate electrode overlapping with the second active layer;
a fifth insulating layer on the third conductive layer;
a valley portion penetrating at least some of the first insulating layer, the second insulating layer, the third insulating layer, the fourth insulating layer, or the fifth insulating layer;
a stacked structure comprising one or more of a plurality of insulating patterns in the valley portion at the same layer as those of the first insulating layer, the second insulating layer, the third insulating layer, the fourth insulating layer, and the fifth insulating layer, respectively;
a sixth insulating layer on the fifth insulating layer, and including at least a portion in the valley portion; and
a light emitting element on the sixth insulating layer.

2. The display device of claim 1, further comprising:
a barrier layer between the first active layer and the substrate;
a lower metal layer between the barrier layer and the first active layer; and
a buffer layer between the lower metal layer and the first active layer,
wherein the valley portion penetrates the buffer layer, and the stacked structure is located directly on the barrier layer.

3. The display device of claim 2, wherein a height of the stacked structure measured from the barrier layer is greater than a height of the second active layer measured from the barrier layer.

4. The display device of claim 3, wherein the stacked structure comprises one or more of a plurality of metal patterns that are located at the same layer as those of the lower metal layer, the first conductive layer, the second conductive layer, and the third conductive layer, respectively.

5. The display device of claim 3, wherein the stacked structure comprises one or more of a plurality of semiconductor patterns that are located at the same layer as those of the first semiconductor layer and the second semiconductor layer, respectively.

6. The display device of claim 2, wherein a height of the stacked structure is greater than a depth of the valley portion.

7. The display device of claim 3, wherein a height of the stacked structure is smaller than a depth of the valley portion.

8. The display device of claim 3, wherein the stacked structure comprises:
a first metal pattern at the same layer as that of the lower metal layer;
a first insulating pattern at the same layer as that of the buffer layer;
a first semiconductor pattern at the same layer as that of the first semiconductor layer;
a second insulating pattern at the same layer as that of the first insulating layer;
a second metal pattern at the same layer as that of the first conductive layer;
a third insulating pattern at the same layer as that of the second insulating layer;
a third metal pattern at the same layer as that of the second conductive layer;
a fourth insulating pattern at the same layer as that of the third insulating layer;
a second semiconductor pattern at the same layer as that of the second semiconductor layer;
a fifth insulating pattern at the same layer as that of the fourth insulating layer;
a fourth metal pattern at the same layer as that of the third conductive layer; and
a sixth insulating pattern at the same layer as that of the fifth insulating layer.

9. The display device of claim 8, wherein the first metal pattern, the first insulating pattern, the first semiconductor pattern, the second insulating pattern, the second metal pattern, the third insulating pattern, the third metal pattern, the fourth insulating pattern, the second semiconductor pattern, the fifth insulating pattern, the fourth metal pattern, and the sixth insulating pattern are sequentially stacked in the stacked structure.

10. The display device of claim 1, wherein the sixth insulating layer surrounds the stacked structure.

11. The display device of claim 1, wherein, in the valley portion, a depth of a portion that does not overlap with the first to third conductive layers, the first semiconductor layer, and the second semiconductor layer is greater than a depth of a portion that overlaps with any one of the first to third conductive layers, the first semiconductor layer, or the second semiconductor layer.

12. The display device of claim 1, wherein the first active layer comprises silicon, and the second active layer comprises an oxide semiconductor.

13. The display device of claim 1, wherein the second conductive layer further comprises a back gate electrode overlapping with the second active layer.

14. The display device of claim 1, further comprising a fourth conductive layer between the fifth insulating layer and the sixth insulating layer, the fourth conductive layer comprising:
a first connection electrode connected to the first active layer; and
a bridge electrode connected to the second active layer.

15. A display device comprising:
a plurality of unit pixel areas;
a first thin film transistor in a unit pixel area from among the plurality of unit pixel areas, and comprising a first active layer on a substrate;
a second thin film transistor in the unit pixel area, and comprising a second active layer at a layer different from that of the first active layer;
a plurality of conductive layers in the unit pixel area, and comprising a plurality of wires and conductive patterns electrically connected to the first thin film transistor and the second thin film transistor;
a valley portion surrounding the unit pixel area, and penetrating at least some of a plurality of insulating layers overlapping with the first thin film transistor and the second thin film transistor; and
a plurality of stacked structures in the valley portion, and comprising one or more patterns at the same layer as those of the plurality of conductive layers, and the plurality of insulating layers, and are stacked.

16. The display device of claim 15, wherein the plurality of unit pixel areas are located along a first direction and a second direction crossing the first direction, and
wherein the valley portion comprises a portion extending in the first direction and the second direction.

17. The display device of claim 16, wherein a stacked structure from among the plurality of stacked structures is located in an area where the portion of the valley portion extending in the first direction and the portion of the valley portion extending in the second direction cross each other.

18. The display device of claim 15, wherein a stacked structure from among the plurality of stacked structures comprises one or more of:
a first semiconductor pattern at the same layer as that of the first active layer; and
a second semiconductor pattern at the same layer as that of the second active layer.

19. The display device of claim 15, wherein a stacked structure from among the plurality of stacked structures comprises one or more of:
a plurality of metal patterns at the same layer as those of the plurality of conductive layers, respectively; and
a plurality of insulating patterns at the same layer as those of the plurality of insulating layers, respectively.

20. The display device of claim 15, wherein a stacked structure from among the plurality of stacked structures does not overlap with the conductive patterns and the wires electrically connected to any one of the first thin film transistor and the second thin film transistor.
